(19) United States
(12) Patent Application Publication
(10) Pub. No.: US 2014/0332754 A1
(43) Pub. Date: Nov. 13, 2014

(54) SEMICONDUCTOR LIGHT-EMITTING DEVICE

(71) Applicant: QINGDAO JASON ELECTRIC CO., LTD., Qingdao (CN)

(72) Inventor: JIANPING ZHANG, Qingdao (CN)

(73) Assignee: QINGDAO JASON ELECTRIC CO., LTD., Qingdao (CN)

(21) Appl. No.: 14/025,717

(22) Filed: Sep. 12, 2013

(30) Foreign Application Priority Data
May 9, 2013 (CN) 201310168615.0

(51) Int. Cl. H01L 33/06

(52) U.S. Cl. CPC H01L 33/06
USPC 257/13

(57) ABSTRACT

The present invention presents a solid-state semiconductor light emitting device with reduced forward voltage and improved quantum efficiency. The light emitting device is characterized by its multiple-quantum-well active-region with opposite composition grading in the quantum barriers and quantum wells along the device epitaxy direction.

### CROSS-REFERENCE TO RELATED APPLICATION

This application claims priority benefit of Chinese patent application serial No. 201310168615.0 filed on May 9, 2013. The entirety of the above-mentioned patent application is hereby incorporated by reference herein and made a part of this specification.

### FIELD OF THE INVENTION

The present invention relates in general to light-emitting device made of polar semiconductors, more particularly to light-emitting device made of group III nitride polar semiconductors with composition gradient in the active-region.

### DESCRIPTION OF THE RELATED ART

Nitride based light-emitting diodes (LEDs) have achieved fast progress in recent years. In the visible spectrum regime, InGaN LEDs are increasingly challenging traditional lighting sources such as fluorescent lamps, due to their technological and economical advantages. Currently, high-efficiency InGaN LED white light lamps with efficacy over 130 lm/watt are commercially available. In the ultraviolet (UV) regime, especially in the UVB (315 nm-280 nm)/UVC (≦280 nm) regimes, AlGaN LEDs, even though still in the technological debut stage, have already outperformed the traditional UV light sources in duration, compactness, and UV-power-density aspects. High-efficiency UVC LEDs will lead to numerous disinfection applications using the UV germicidal effect, making revolutionary advances in food safety, water treatment, and medical applications.

Currently, most UV LEDs with emissions shorter than 350 nm adopt the layer structure developed by Zhang et al (See below), which contains a c-plane sapphire as UV transparent substrate, a high-quality AlN layer coated over the substrate serving as epitaxy template, and a set of AlN/AlGaN superlattice for dislocation and strain management. The utilization of high-quality AlN template and AlN/AlGaN superlattice enables the growth of high-quality highly-conductive n-type AlGaN electron supplier layer, which injects electrons into the following AlGaN-based multiple quantum well (MQW) active-region. On the other side of the MQW active-region are an AlGaN electron-blocking layer, an AlGaN hole injection layer, a hole supplier layer and a p-type GaN layer for ohmic contact formation. The prior art AlGaN LED structures can be found in the references. (J. P. Zhang et al, Milliwatt power deep ultraviolet light-emitting diodes over sapphire with emission at 278 nm, APPLIED PHYSICS LETTERS 81, 4910 (2002); J. P. Zhang et al, Crack-free thick AlGaN grown on sapphire using AlN/AlGaN superlattices for strain management, APPLIED PHYSICS LETTERS 80, 3542 (2002)).

On the other hand, group III nitrides are polar semiconductors. This means that interface space charges are inevitably generated when forming heterostructures using nitrides, due to the discontinuity of spontaneous and piezoelectric polarizations at the heterointerface. The spontaneous and piezoelectric polarizations in nitrides have maximal values along c-direction (<0001>), and the resultant interface space charge density in GaN/InGaN and AlGaN/AlGaN c-oriented heterostructures can exceed 10¹³/cm², leading to electric field larger than 1 MV/cm resulting in strong band structure distortion. Illustrated in FIG. 1 is the band structure of a quantum well in a prior art UV LED active-region. For simplicity, only one quantum well embedded in two quantum barriers is shown to highlight the band structure distortion. Two heterointerfaces, S1, and S2 are formed between the quantum well and the quantum barriers. Electrons in the conduction band (C.B.) and holes in the valence band (V.B.) are injected into the quantum well through S1 from the left side and S2 from the right side, respectively. Due to the polarization discontinuity at the heterointerfaces, there are negative space charges on S1 and positive space charges on S2, building up an electric field E_{PL}_{_{—}}_{QW} in the quantum well pointing from S2 to S1 (against c-direction). Since there are more than one quantum wells in the active region, the neighboring interface space charges also give rise to another electric field E_{PL}_{_{—}}_{QB} in the quantum barriers, pointing in the opposite direction of E_{PL}_{_{—}}_{QW}. Electric fields E_{PL}_{_{—}}_{QW} and E_{PL}_{_{—}}_{QB} thus tilt the band structure of the MQW active-region. E_{PL}_{_{—}}_{QB} impedes electrons and holes injection into the quantum wells, whereas E_{PL}_{_{—}}_{QW} reduces the wavefunction overlapping of electrons and holes in the quantum wells. These effects lead to higher device forward voltage and lower internal quantum efficiency, respectively.

In the prior art, quaternary AlInGaN materials have been proposed to replace binary (AlN, GaN, and InN) and ternary (AlGaN, AlInN and InGaN) materials for heterostructure formation, owing to the flexibility of nearly independent bandgap and lattice constant adjustment in the quaternaries for a reduced polarization mismatch. (e.g.: “Quaternary AlInGaN Multiple Quantum Wells for Ultraviolet Light Emitting Diodes”, J. P. Zhang, et al, Jpn J. Appl. Phys. 40, L921-L924 (2001); U.S. Pat. No. 7,348,606). In principle, quaternary heterostructure approach can result in high quantum efficiency for MQW active-regions. However, since the optimal incorporation conditions of Al and In are not compatible with each other, it is difficult to obtain high-quality AlInGaN quaternary materials.

The present invention discloses MQW embodiments having reduced polarization field and improved quantum confinement effect, and provides ultraviolet LEDs with improved efficiency and reduced forward voltage.

### SUMMARY OF THE INVENTION

The present invention discloses a light emitting device with improved quantum efficiency and forward voltage. Throughout the specification, the term III-nitride or nitride in general refers to metal nitride with cations selecting from group IIIA of the periodic table of the elements. That is to say, III-nitride includes AlN, GaN, InN, their ternary (AlGaN, InGaN, InAlN) and quaternary (AlInGaN) alloys. III-nitride or nitride can also include small compositions of transition metal nitride such as TiN, ZrN, HfN with molar fraction not larger than 10%. For example, III-nitride or nitride may include AlₓIn_{y}Ga_{z}Ti_{(1-x-y-z)}N, AlₓIn_{y}Ga_{z}Zr_{(1-x-y-z)}N, AlₓIn_{y}Ga_{z}Hf_{(1-x-y-z)}N, with (1-x-y-z)≦10%. A III-nitride layer or active-region means that the layer or active-region is made of III-nitride semiconductors.

According to one aspect of the present invention, composition grading, for example, Al-composition grading is used to modify the band structure of polar semiconductor heterostructures in order to mitigate the polarization field induced band structure distortion. Al-composition changes can result in AlInGaN bandgap width changes. For example, increasing Al-composition can enlarge the bandgap width, enabling conduction band moving upwards and valence band moving downwards. These movements can be used to mitigate the band edge tilt arising from the polarization field of polar semiconductor heterostructures. In some embodiments, composition grading is used to alleviate the band edge tilt in quantum wells and quantum barriers, leading to improved device forward voltage and quantum efficiency.

Another aspect of the present invention provides a solid-state ultraviolet light emitting device, comprising an N-type layer, a P-type layer and a light-emitting active-region sandwiched in-between the N-type and the P-type layer, and the light-emitting active-region contains at least one quantum well, embedded in quantum barriers, wherein the quantum wells and quantum barriers have composition gradients along the device epitaxy direction.

Another aspect of the present invention provides a solid-state ultraviolet light emitting device, comprising an N-type layer, a P-type layer and a light-emitting active-region sandwiched in-between the N-type and the P-type layer, and the light-emitting active-region contains at least one quantum well, embedded in quantum barriers, wherein the quantum wells and quantum barriers have opposite composition gradients along the device epitaxy direction.

Optionally, the light-emitting device is made of wurtzite group III nitrides and the main epitaxial growth plane is (0001) c-plane, meaning an epitaxy direction along [0001] direction.

Optionally, the Al-composition in the quantum wells and quantum barriers is within 1%-90%. Preferably, the Al-composition of the quantum wells is within 1%-60%, and the Al-composition of the quantum barriers is within 5%-85%.

Optionally, the composition gradients of the quantum wells and the quantum barriers are evidenced as composition linear or nonlinear changes, or abrupt changes, or stair-case changes.

Preferably, the Al-composition of the quantum wells increases along the device epitaxy direction, and Al-composition of the quantum barriers decreases along the device epitaxy direction, when the epitaxy direction is along c-direction [0001].

Preferably, the Al-composition of the quantum wells linearly increases along the device epitaxy direction with the gradient within 0.6% per nanometer to 12% per nanometer, and the Al-composition of the quantum barriers linearly decreases along the device epitaxy direction with the gradient within −0.1% per nanometer to −2% per nanometer.

Optionally, the donor concentration in the quantum wells and quantum barriers can possess linear, nonlinear, abrupt, or stair-case change along the device epitaxy direction.

Optionally, the donor concentration in the quantum barriers increases along the device epitaxy direction, when the epitaxy direction is along c-direction [0001].

Preferably, the donor concentration in the quantum barriers possesses a gradient within 10¹⁷ cm⁻³/nm to 10¹⁸ cm⁻³/nm along the device epitaxy direction.

Optionally, the donor concentration in the quantum wells decreases along the device epitaxy direction, when the epitaxy direction is along c-direction [0001].

Preferably, the donor concentration in the quantum wells possesses a gradient within −2×10¹⁸ cm⁻³/nm to −2×10¹⁷ cm⁻³/nm along the device epitaxy direction.

Furthermore, the (average) Al-composition of the quantum barriers can be less than or equal to the Al-composition of the N-type layer. Preferably, the Al-composition of the N-type layer is about 1.1 to 1.2 times of that of the quantum barriers.

### BRIEF DESCRIPTION OF THE DRAWINGS

The accompanying drawings, which are included to provide a further understanding of the invention and constitute a part of this application, illustrate embodiments of the invention and together with the description serve to explain the principle of the invention. Like reference numbers in the figures refer to like elements throughout, and a layer can refer to a group of layers associated with the same function.

FIG. 1 illustrates the band structure of a quantum well of a prior art UV LED.

FIG. 2A illustrates the Al-composition distribution in a quantum well of the active-region of the UV LEDs according to the embodiments 1 and 2 of the present invention.

FIG. 2B illustrates the Al-composition distribution in a quantum well of the active-region of the UV LEDs according to the embodiment 3 of the present invention.

FIG. 2C illustrates the Al-composition and donor concentration distribution in a quantum well of the active-region of the UV LEDs according to the embodiment 4 of the present invention.

FIG. 3 plots the experimental external quantum efficiency and the simulated internal quantum efficiency of a 280 nm LED fabricated according to embodiment 1 of the present invention.

FIG. 4 illustrates the layered structure of a UV LED according to the embodiment 1 of the present invention.

### DETAILED DESCRIPTION OF EMBODIMENTS

In the following contents, nitride light-emitting devices or structures are used as embodiments to elucidate the principle and spirit of the present invention. Those of ordinary skills in the field can apply the teachings in this specification and given by the following embodiments of nitride light-emitting devices or structures to II-VI semiconductor and other polar semiconductor devices or light-emitting devices without creative work.

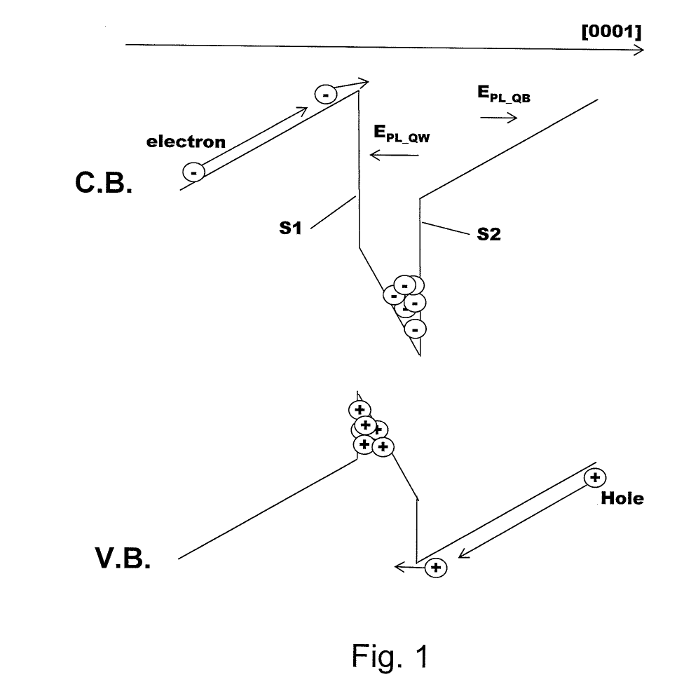

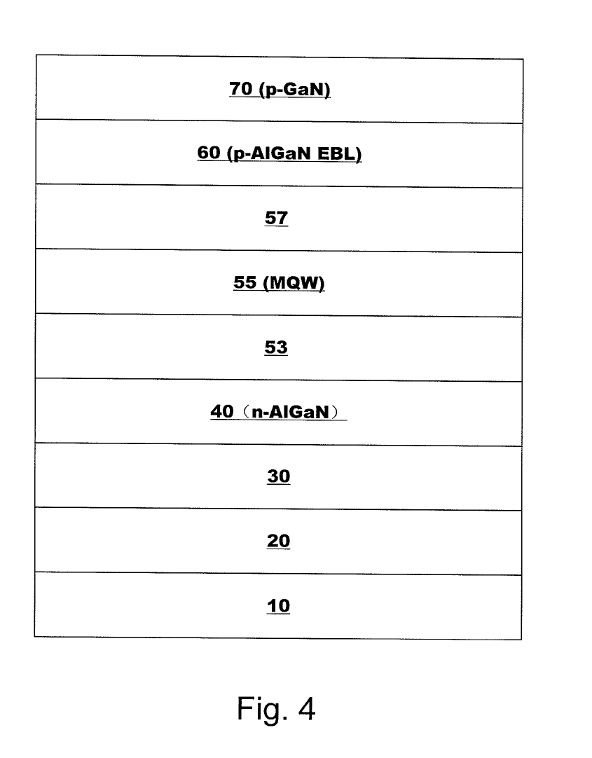

Embodiment 1 according to the present invention is a wurtzite [0001]-oriented group III nitride ultraviolet light emitting diode, with the layered structure illustrated in FIG. 4. As shown substrate 10 can be selected from (111) Si, (0001) sapphire (flat or patterned), AlN, GaN, AlGaN, and the like. Formed over substrate 10 is layer 20 as epitaxy template, preferably being made of AlN, or AlGaN with high Al-composition (e.g. higher than 60%). The thickness of layer 20 is preferably to be more than 100 nm, for example, 1000-3000 nm. Following layer 20 is layer 40 serving as electron supplier layer made of N-type AlGaN, with enough thickness for good electrical conduction and material quality, preferably to be 2 μm or thicker. In order to improve the material quality of layer 40, optionally inserted in-between layer 20 and layer 40 is a strain management and defect filtering structure 30. Structure 30 can be AlGaN/AlGaN multiple-layer heterostructure, or AlN/AlGaN multiple-layer heterostructure, or AlN/AlGaN superlattice. Epitaxially deposited over layer 40 are structure 53 and 57, sandwiching the light-emitting multiple-quantum-well (MQW) active-region 55. Structure 53 is a heavily n-type doped AlGaN layer or AlGaN/AlGaN heterostructure or superlattice, and structure 57 is a heavily p-type doped AlGaN layer or AlGaN/AlGaN heterostructure or superlattice. The dopant concentration in structure 53 and 57 is preferably to be higher than 5×10¹⁸ cm⁻³ and 5×10¹⁹ cm ⁻³, respectively, in order to build up a strong PN junction field to mitigate the quantum well polarization field (FIG. 1, E_{PL}_{_{—}}_{QW}) for improved light-emitting quantum efficiency. Formed over structure 57 are a p-type AlGaN electron blocking layer 60 and a p-type GaN ohmic contact layer 70.

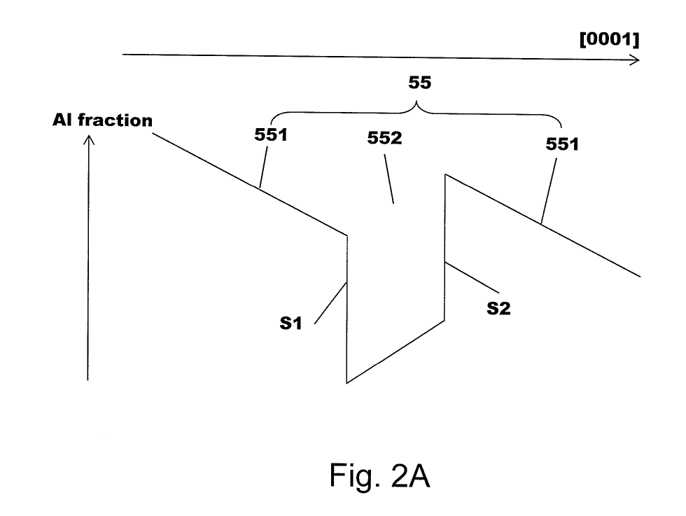

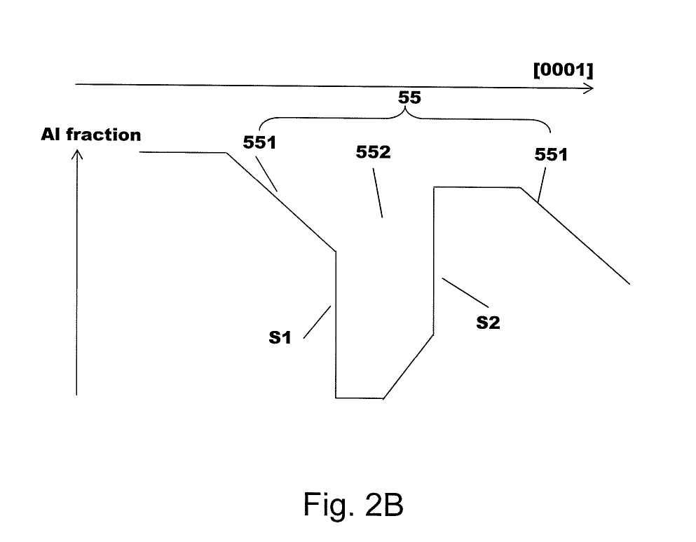

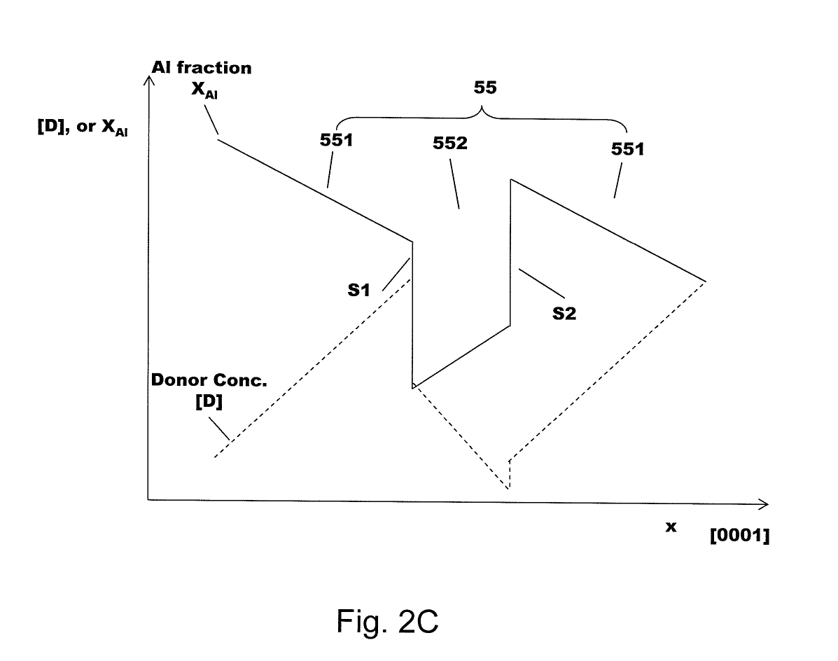

Embodiment 1 is further characterized by its MQW active-region design. The quantum wells and quantum barriers in the MQW of embodiment 1 are of non-uniform composition distribution. Preferably, they are of gradually changing compositions, more preferably, the composition of the quantum wells and quantum barriers are of opposite gradient. Illustrated in FIG. 2A is the Al-composition distribution of one quantum well (552) and two quantum barriers (551) of the MQW active-region 55. MQW active-region 55 may contain more than one such quantum well separated by respective quantum barriers. Quantum well 552 and quantum barrier 551 may have heterointerface S1 or S2, respectively.

As seen from FIG. 2A, along the device formation epitaxy direction x (e.g., [0001]), quantum barriers 551 have a constant (A) negative Al-composition (x_{Al-QB}) gradient and quantum well 552 has a constant (B) positive Al-composition (x_{Al-QW}) gradient, i.e., dx_{Al-QB}/dx=A<0, and dx_{Al-QW}/dx=B>0. Using the Al-composition distribution in MQW illustrated in FIG. 2A to compensate the band edge tilt arising from the polarization field will lead to more flat band edge for quantum wells and quantum barriers, leading to reduced device forward voltage and increase quantum efficiency.

Preferably, as illustrated in FIG. 2A, the Al-compositions in the quantum wells and quantum barriers possess gradual linear changes (constant gradient) in the device formation epitaxy direction. The Al-composition can also have gradual nonlinear changes and abrupt changes such as stair-case changes in the device formation epitaxy direction, i.e., possessing changing gradient or delta-function type gradient.

UV LED embodiment 1 with the MQW active-region having Al-composition distribution illustrated in FIG. 2A may emit UV light in the wavelength range from 230 nm to 350 nm. The (average) quantum barrier Al-composition is in the range of 20%-85%, and the (average) quantum well Al-composition is in the range of 5%-70%. The MQW may contain In-composition less than 1%. The quantum well Al-composition gradient (dx_{Al-QW}/dx) along the device formation epitaxy direction is within 0.6% per nanometer to 6% per nanometer (i.e., Al-composition increases from value x to a value within x+0.6% to x+6% within one nanometer), and the quantum barrier Al-composition gradient (dx_{Al-QB}/dx) along the device formation epitaxy direction is within −0.1% per nanometer to −2% per nanometer.

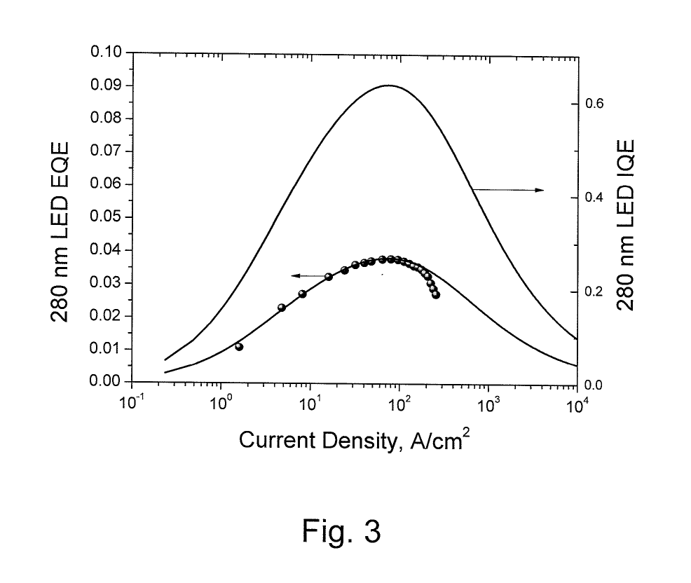

Plotted in FIG. 3 are the quantum efficiency data of a 280 nm UV LED fabricated according to embodiment 1 of the present invention. The experimental external quantum efficiency (EQE) of this LED reached 3.5% at current density 75 A/cm². Using carrier recombination ABC model to simulate the EQE data reveals maximum internal quantum efficiency (IQE) of 64% and light extraction efficiency of 6%, indicating UV LEDs according to embodiment 1 have high internal quantum efficiency.

Embodiment 2 is similar to embodiment 1 except that electron supplier layer 40 has higher Al-composition than the average Al-composition of quantum barrier 551. Preferably, the Al-composition of layer 40 is about 1.1-1.2 times of the average Al-composition of quantum barrier 551. This arrangement exerts biaxial compressive strain to quantum barriers 551, introducing piezoelectric polarization field to compensate spontaneous polarization field within quantum barriers 551, facilitating carriers' injection into quantum wells 552 and leading to reduced device forward voltage.

Embodiment 3 distinguishes from embodiment 1 and 2 in the MQW active-region Al-composition distribution, which is illustrated in FIG. 2B.

As seen, for the quantum barrier Al-composition x_{Al}_{_{—}}_{QB}, along the device formation epitaxy direction (e.g., [0001]),
dx_{Al-QB}/dx=0, for x<0.5 L_{QB}, and,
dx_{Al-QB}/dx<0, for x≧0.5 L_{QB}, here L_{QB} is the quantum barrier thickness.

This is to say, at the beginning of the quantum barrier, Al-composition gradient is zero (constant Al-distribution), and for the rest of the quantum barrier the Al-composition has negative gradient (Al-decreasing). This gradient is preferably to be within −0.1% per nanometer to −2% per nanometer.

Further, for the quantum well Al-composition x_{Al-QW}, the distribution along the epitaxy direction satisfies the following relationship.
dx_{Al-QW}/dx=0, for x<0.5 L_{QW}, and,
dx_{al-QW}/dx>0, for x≧0.5 L_{QW}, here L_{QW} is the quantum well thickness.

This is to say, at the beginning of the quantum well, Al-composition gradient is zero (constant Al-distribution), and for the rest of the quantum well the Al-composition has positive gradient (Al-increasing). This gradient is preferably to be within 0.6% per nanometer to 12% per nanometer.

Embodiment 4 distinguishes from embodiment 1 in terms of the MQW active-region doping. For this embodiment, the Al-composition and donor concentration ([D]) distributions in one quantum well and two quantum barriers of the MQW active-region 55 are illustrated in FIG. 2C. As seen, besides the Al-composition grading within the MQW, donor concentration within the MQW is also graded. Along the epitaxy direction ([0001]), donor concentration [D] in the quantum barriers increases, while [D] in the quantum wells can be zero or a constant value, or preferably gradually decrease. Preferably, as illustrated in FIG. 2C, the donor concentration in the quantum wells and quantum barriers possess gradual linear changes. It can also have gradual nonlinear changes and abrupt changes such as stair-case changes.

The donor can be Si or Ge. In quantum barriers 551 the donor concentration can increase from zero to 1×10¹⁹ cm ⁻³, or from 1×10¹⁷ cm⁻³ to 1×10¹⁹ cm ⁻³,along the epitaxy direction [0001]. When possessing linear change rate, the donor concentration in the quantum barriers can have a gradient of 10¹⁷ cm⁻³/nm to 10¹⁸ cm⁻³/nm along the epitaxy direction. While [D] in the quantum wells can decrease from 5×10¹⁸ cm⁻³ to zero, or from 1×10¹⁸ cm⁻³ to zero, or from 1>10¹⁸ cm⁻³ to 1×10¹⁷ cm⁻³. Preferably, it has a linear gradient of −2×10¹⁸ cm⁻³/nm to −2×10¹⁷ cm⁻³/nm along the epitaxy direction [0001].

[D] in quantum barriers 551 can also have abrupt changes, for example, in the first part of a quantum barrier (epitaxially formed firstly), [D] can be zero or 5×10¹⁷ cm⁻³, in the rest part, [D] can be 3×10¹⁸ cm⁻³ or 5×10¹⁸ cm⁻³. Similarly, [D] in quantum wells 552 can also have abrupt changes, for example, in the first part of a quantum well (epitaxially formed firstly), [D] can be 1×10¹⁸ cm⁻³ or 5×10¹⁷ cm⁻³, in the rest part, [D] can be 3×10¹⁷ cm⁻³ or zero.

This embodiment employs the built-in electric field from the donor concentration grading to mitigate the polarization field within the MQW active-region, leading to improved internal quantum efficiency and reduced device forward voltage.

The present invention has been described using exemplary embodiments. However, it is to be understood that the scope of the present invention is not limited to the disclosed embodiments. On the contrary, it is intended to cover various modifications and similar arrangement or equivalents. The scope of the claims, therefore, should be accorded the broadest interpretation so as to encompass all such modifications and similar arrangements and equivalents.

1. A light emitting device comprising:
an N-type layer;
a P-type layer, and,
an active region sandwiched between the N-type layer and the P-type layer, wherein the active-region contains at least one quantum well made of III-nitride embedded by quantum barriers made of III-nitride, the quantum well and the quantum barriers are of opposite Al-composition gradient along a device formation epitaxy direction.

2. The light-emitting device according to claim 1, wherein the quantum well and quantum barriers have 1%-90% Al-composition, respectively.

3. The light-emitting device according to claim 2, wherein the quantum well has 1%-70% Al-composition and the quantum barriers have 5%-85% Al-composition.

4. The light-emitting device according to claim 1, wherein the Al-composition gradient of the quantum well and quantum barriers are constant, or gradually changing, or of delta function type.

5. The light-emitting device according to claim 1, wherein the Al-composition of the quantum well increases along the device formation epitaxy direction and the Al-composition of the quantum barriers decreases along the device formation epitaxy direction.

6. The light-emitting device according to claim 5, wherein the Al-composition of the quantum well linearly increases along the device formation epitaxy direction, with a gradient in the range of 0.6% per nanometer to 12% per nanometer, and the Al-composition of the quantum barriers linearly decreases along the device formation epitaxy direction, with a gradient in the range of −0.1% per nanometer to −2% per nanometer.

7. The light-emitting device according to claim 1, wherein the N-type layer is made of III-nitride and Al-composition of the N-type layer is equal to or larger than average Al-composition of the quantum barriers.

8. The light-emitting device according to claim 7, wherein the Al-composition of the N-type layer is 1.1 to 1.2 times of the average Al-composition of the quantum barriers.

9. The light-emitting device according to claim 1, wherein said active-region is made of wurtzite group III nitride semiconductors with the device formation epitaxy direction along [0001] c-direction.

10. The light-emitting device according to claim 1, wherein donor concentration in the quantum barriers increases along the device formation epitaxy direction.

11. The light-emitting device according claim 10, wherein the donor concentration in the quantum barriers has a gradient of 10¹⁷ cm ⁻³ per nanometer to 10¹⁸ cm⁻³ per nanometer along the device formation epitaxy direction.

12. The light-emitting device according to claim 1, wherein donor concentration in the quantum well decreases along the device formation epitaxy direction.

13. The light-emitting device according claim 12, wherein the donor concentration in the quantum well has a gradient of −2×10¹⁸ cm⁻³ per nanometer to −2×10¹⁷ cm⁻³ per nanometer along the device formation epitaxy direction.

14. The light-emitting device according to claim 12, wherein the donor concentration in the quantum well has linear, nonlinear, or stair-case gradient along the device formation epitaxy direction.

15. The light-emitting device according to claim 10, wherein the donor concentrations in the quantum barriers has linear, nonlinear, or stair-case gradient along the device formation epitaxy direction.

16. A light emitting device comprising:
an N-type layer;
a P-type layer, and,
an active region sandwiched between the N-type layer and the P-type layer, wherein the active-region contains at least one quantum well made of a first semiconductor material embedded by quantum barriers made of a second semiconductor material, both the first semiconductor material and the second semiconductor material contain aluminum composition, and the quantum well and the quantum barriers are of opposite composition gradient along a device formation epitaxy direction.

17. The light-emitting device according to claim 16, wherein the quantum well and quantum barriers have 1%-90% Al-composition, respectively.

18. The light-emitting device according to claim 17, wherein the Al-composition of the quantum well increases along the device formation epitaxy direction and the Al-composition of the quantum barriers decreases along the device formation epitaxy direction.

19. The light-emitting device according to claim 18, wherein the Al-composition of the quantum well linearly increases along the device formation epitaxy direction, with a gradient in the range of 0.6% per nanometer to 12% per nanometer, and the Al-composition of the quantum barriers linearly decreases along the device formation epitaxy direction, with a gradient in the range of −0.1% per nanometer to −2% per nanometer.

20. The light-emitting device according to claim 16, wherein the first semiconductor material and the second semiconductor material are III-nitride.
